(19) United States
(12) Patent Application Publication
(10) Pub. No.: US 2020/0107453 A1
(43) Pub. Date: Apr. 2, 2020

(54) CONDUCTIVE INK FOR FORMING SIGNAL CONNECTION, SIGNAL REFERENCING, AND SHIELDING FEATURESON PRINTED CIRCUIT BOARDS

(71) Applicant: International Business Machines Corporation, Armonk, NY (US)

(72) Inventors: MICHAEL CHRISTO, Round Rock, TX (US); DAVID GREEN, Austin, TX (US); DIANA D. ZUROVETZ, Round Rock, TX (US)

(73) Assignee: International Business Machines Corporation, Armonk, NY (US)

(21) Appl. No.: 16/144,898

(22) Filed: Sep. 27, 2018

(51) Int. Cl. H05K 3/24; H05K 1/09; H05K 9/00; G05B 19/042; H05K 3/12; H05K 1/02

(52) U.S. Cl. CPC H05K 3/246; H05K 1/092; H05K 9/0039; G05B 19/0426; H05K 3/064; H05K 1/0218; H05K 1/0298; H05K 2201/0715; H05K 2203/1453; H05K 3/1233

(57) ABSTRACT

A printed circuit board (PCB) stack having a plurality of layers is received. A conformal coating layer is applied to one or more external layers of the plurality of layers. A conductive ink is applied to one or more portions of the protective conformal coating layer to form one or more conductive features on the protective conformal coating layer.

### TECHNICAL FIELD

The present invention relates generally to a method for fabricating printed circuit boards and a structure formed by the method. More particularly, the present invention relates to a method for fabricating printed circuit boards using conductive ink for forming signal connection, signal referencing, and shielding features and a structure formed by the method.

### BACKGROUND

A printed circuit board (PCB) is a structure that mechanically supports and electrically connects electronic components of one or more circuits. During manufacture of a PCB, conductive tracks, pads, and other features are etched from one or more sheet layers of conductive material, such as copper, laminated onto and/or between sheet layers of a non-conductive substrate are used to electrically connect the electronic components. The electronic components are generally soldered onto the PCB to electrically connect and mechanically fasten the electronic components to the PCB.

PCBs can be constructed as single-sided with one conductive layer (e.g. a copper layer), double-sided with two conductive layers, or multi-layer having one or more outer and inner conductive layers sandwiched between layers of insulating material. Multi-layer PCBs allow for much higher component density.

During manufacture, chemical etching is used to divide a conducting layer into separate conducting lines called tracks or circuit traces, pads for connections, and features such as solid conductive areas for shielding or other purposes. Conductors on different layers are connected with vias, which are typically copper-plate holes that function as electrical tunnels through the insulating substrate. A common insulating substrate is FR-4 glass epoxy. A pattern to be etched into each conductive layer is called the “artwork”. The etching is usually performed using photoresist which is coated onto the PCB, then exposed to light projected in the pattern of the artwork. The resist material protects the conductive material from dissolution into the etching solution. The etched board is then cleaned of the resist material such that conductive material in the form of the pattern remains.

### SUMMARY

The illustrative embodiments provide a method, apparatus, and a computer usable program product. An embodiment of a method includes receiving a printed circuit board (PCB) stack having a plurality of layers. The embodiment further includes applying a conformal coating layer to one or more external layers of the plurality of layers. The embodiment still further includes applying conductive ink to one or more portions of the protective conformal coating layer to form one or more conductive features on the protective conformal coating layer.

In another embodiment, the conductive ink is applied using a silk-screening process. In another embodiment, the conductive ink is applied using a stenciling process.

In another embodiment, the one or more conductive feature includes a signal referencing feature. In another embodiment, the signal referencing feature is coupled to a signal line of the PCB to allow external referencing of the signal line.

In another embodiment, the one or more conductive features includes a signal shielding feature. In another embodiment, the signal shielding feature is positioned proximate to one or more of an electronic component or a signal line of the PCB.

In another embodiment, the one or more conductive features includes rework wiring. In another embodiment, the one or more conductive features includes a signal connection feature.

In another embodiment, the one or more external layers includes a conductive layer of the PCB stack.

An embodiment of an apparatus includes a printed circuit board (PCB) stack having a plurality of layers. The embodiment further includes a conformal coating layer applied to one or more external layers of the plurality of layers. The embodiment still further includes a conductive ink applied to one or more portions of the protective conformal coating layer to form one or more conductive features on the protective conformal coating layer.

In another embodiment, the conductive ink is applied using a silk-screening process. In another embodiment, the conductive ink is applied using a stenciling process.

In another embodiment, the one or more conductive feature includes a signal referencing feature. In another embodiment, the signal referencing feature is coupled to a signal line of the PCB to allow external referencing of the signal line.

In another embodiment, the one or more conductive features includes a signal shielding feature. In another embodiment, the signal shielding feature is positioned proximate to one or more of an electronic component or a signal line of the PCB.

An embodiment includes a computer usable program product. The computer usable program product includes one or more computer-readable storage devices, and program instructions stored on at least one of the one or more storage devices.

In an embodiment, the computer usable code is stored in a computer readable storage device in a data processing system, and wherein the computer usable code is transferred over a network from a remote data processing system.

In an embodiment, the computer usable code is stored in a computer readable storage device in a server data processing system, and wherein the computer usable code is downloaded over a network to a remote data processing system for use in a computer readable storage device associated with the remote data processing system.

### BRIEF DESCRIPTION OF THE DRAWINGS

The novel features believed characteristic of the invention are set forth in the appended claims. The invention itself, however, as well as a preferred mode of use, further objectives and advantages thereof, will best be understood by reference to the following detailed description of the illustrative embodiments when read in conjunction with the accompanying drawings, wherein:

FIG. 1 depicts a block diagram of a network of data processing systems in which illustrative embodiments may be implemented;

FIG. 2 depicts a block diagram of a data processing system in which illustrative embodiments may be implemented;

FIG. 3 depicts a cross-section view of a portion of a process according to an illustrative embodiment.

FIG. 4 depicts a cross-section view of another portion of the process according to an illustrative embodiment;

FIG. 5 depicts a top view of a PCB stack having conductive features formed using conductive ink by a stenciling or silk-screening process in accordance with an illustrative embodiment;

FIG. 6 depicts a flowchart of an example process for designing and fabricating printed circuit boards using conductive ink for forming signal connection, signal referencing, and shielding features in accordance with an illustrative embodiment; and

FIG. 7 depicts a flowchart of an example process for fabricating printed circuit boards using conductive ink for forming conductive features in accordance with an illustrative embodiment.

### DETAILED DESCRIPTION

The illustrative embodiments relate to a method for fabricating printed circuit boards (PCBs) using conductive ink for forming signal referencing and shielding and a structure formed by the method. The illustrative embodiments recognize that as the wiring densities of PCBs increase, limited real estate exists for externally routing critical nets away from noise sources. A “net” is a collection of interconnected components in a PCB. The illustrative embodiments further recognize that coupling of noise from nearby aggressors and outside sources results in increased crosstalk and subsequently increased bit error rate (BER), affecting system reliability.

The illustrative embodiments recognize that silk-screen printing is currently used to place text identifiers near PCB components, indicate component polarities, show component shapes, and provide other labelling on the PCB. The silk-screen identifiers are typically printing on a surface of the PCB near the end of the PCB manufacturing process. Originally, the silk-screen was applied using a traditional silk-screen process using a silk-screen printing epoxy, however other processes are increasingly being used such as ink jet printing or liquid photo imaging.

One or more embodiments described herein utilize existing silk-screen hardware and processes to apply a conductive ink coating to one or more external layers of a PCB stack to form one or more conductive features to improve signal referencing, shielding, as well as allow for the addition of surface connection such as for PCB reworking. PCB reworking refers to refinishing operations or repair operations of a PCB assembly to implement engineering changes to the PCB assembly that may be required at a late stage in the design and manufacturing process. Conductive ink is known and typically consists of a solution mixed with graphite, silver, or other conductive particles. In an embodiment, the conductive ink is applied to a PCB after a protective, insulative coating has been applied to form conductive features for forming signal referencing, signal shielding, or for PCB reworks.

In an embodiment of work flow, a user, such as a PCB designer, uses a PCB computer aided design (CAD) program to draw conductive ink silk-screen features using a conductive silk-screen layer. In the embodiment, CAD files necessary for PCB manufacturing including the conductive ink silk-screen layer are transmitted to a PCB manufacturer. In response to receiving the CAD files, the PCB manufacturer fabricates a multilayer PCB stack, or alternately receives an already fabricated multiplayer PCB stack. The manufacturer prepares stenciling or silk-screening hardware for use with conductive ink, and applies the conductive ink to a top and/or bottom layer of the PCB using a stenciling or silk-screening process to form conductive features on the top and/or bottom layers of the PCB.

The illustrative embodiments recognize that a raw PCB or card manufacturing process may take weeks for a standard PCB or card. During this time, it is possible that the designers of the PCB may have discovered that a rework must be applied to the design. One or more embodiments, allow for a typical ‘yellow wire’ rework to be performed late in the manufacturing process using a conductive coating ink coating. In a particular example, a printed circuit board designer sends a conductive silk-screen layer file to the manufacturer to implement the rework.

One or more embodiments provide for an additional layer of shielding to a PCB that is readily applied during the PCB manufacturing process. An advantage of one or more embodiments, is that application of the conductive ink allows shielding to be placed in the design without using dedicated conductive layers of the PCB stack.

An embodiment can be implemented as a software application. The application implementing an embodiment can be configured as a modification of an existing fabrication system, as a separate application that operates in conjunction with an existing fabrication system, a standalone application, or some combination thereof. For example, the application causes the fabrication system to perform the steps described herein, to fabricate printed circuit boards (PCBs) using conductive ink for forming signal connection, signal referencing, and shielding features.

For the clarity of the description, and without implying any limitation thereto, the illustrative embodiments are described using a multilayer PCB stack. An embodiment can be implemented with different types and/or numbers of PCB stack layers or electronic cards within the scope of the illustrative embodiments.

Furthermore, simplified diagrams of the example PCBs are used in the figures and the illustrative embodiments. In an actual fabrication of a PCB, additional structures that are not shown or described herein may be present without departing the scope of the illustrative embodiments. Similarly, within the scope of the illustrative embodiments, a shown or described structure in the example PCBs may be fabricated differently to yield a similar operation or result as described herein.

Differently shaded portions in the two-dimensional drawing of the example PCBs are intended to represent different structures in the example PCBs, as described herein. The different structures may be fabricated using suitable materials that are known to those of ordinary skill in the art.

A specific shape or dimension of a shape depicted herein is not intended to be limiting on the illustrative embodiments. The shapes and dimensions are chosen only for the clarity of the drawings and the description and may have been exaggerated, minimized, or otherwise changed from actual shapes and dimensions that might be used in actually fabricating PCBs according to the illustrative embodiments.

Furthermore, the illustrative embodiments are described with respect to multilayer PCBs only as an example. The steps described by the various illustrative embodiments can be adapted for fabricating other electronic circuits devices in a similar manner, and such adaptations are contemplated within the scope of the illustrative embodiments.

An embodiment when implemented in an application causes a fabrication process to perform certain steps as described herein. The steps of the fabrication process are depicted in the several figures. Not all steps may be necessary in a particular fabrication process. Some fabrication processes may implement the steps in different order, combine certain steps, remove or replace certain steps, or perform some combination of these and other manipulations of steps, without departing the scope of the illustrative embodiments.

A method of an embodiment described herein, when implemented to execute on a device or data processing system, comprises substantial advancement of the functionality of that device or data processing system in fabricating PCBs. An embodiment provides a method for fabricating PCBs.

The illustrative embodiments are described with respect to certain types of devices, contacts, layers, planes, structures, materials, dimensions, numerosity, data processing systems, environments, components, and applications only as examples. Any specific manifestations of these and other similar artifacts are not intended to be limiting to the invention. Any suitable manifestation of these and other similar artifacts can be selected within the scope of the illustrative embodiments.

Furthermore, the illustrative embodiments may be implemented with respect to any type of data, data source, or access to a data source over a data network. Any type of data storage device may provide the data to an embodiment of the invention, either locally at a data processing system or over a data network, within the scope of the invention. Where an embodiment is described using a mobile device, any type of data storage device suitable for use with the mobile device may provide the data to such embodiment, either locally at the mobile device or over a data network, within the scope of the illustrative embodiments.

The illustrative embodiments are described using specific code, designs, architectures, protocols, layouts, schematics, and tools only as examples and are not limiting to the illustrative embodiments. Furthermore, the illustrative embodiments are described in some instances using particular software, tools, and data processing environments only as an example for the clarity of the description. The illustrative embodiments may be used in conjunction with other comparable or similarly purposed structures, systems, applications, or architectures. For example, other comparable mobile devices, structures, systems, applications, or architectures therefor, may be used in conjunction with such embodiment of the invention within the scope of the invention. An illustrative embodiment may be implemented in hardware, software, or a combination thereof.

The examples in this disclosure are used only for the clarity of the description and are not limiting to the illustrative embodiments. Additional data, operations, actions, tasks, activities, and manipulations will be conceivable from this disclosure and the same are contemplated within the scope of the illustrative embodiments.

Any advantages listed herein are only examples and are not intended to be limiting to the illustrative embodiments. Additional or different advantages may be realized by specific illustrative embodiments. Furthermore, a particular illustrative embodiment may have some, all, or none of the advantages listed above.

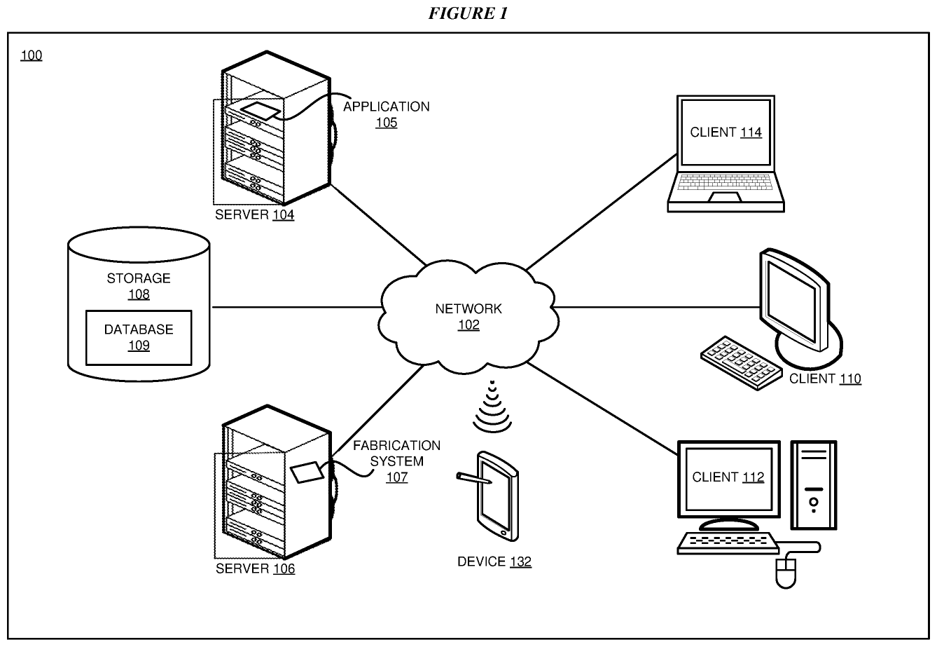

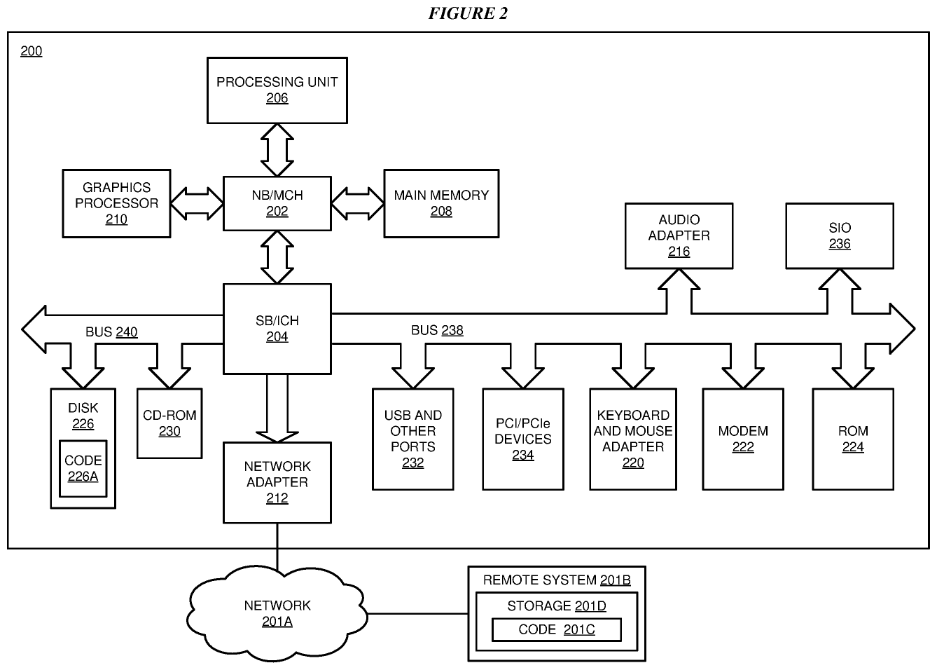

With reference to the figures and in particular with reference to FIGS. 1 and 2, these figures are example diagrams of data processing environments in which illustrative embodiments may be implemented. FIGS. 1 and 2 are only examples and are not intended to assert or imply any limitation with regard to the environments in which different embodiments may be implemented. A particular implementation may make many modifications to the depicted environments based on the following description.

FIG. 1 depicts a block diagram of a network of data processing systems in which illustrative embodiments may be implemented. Data processing environment 100 is a network of computers in which the illustrative embodiments may be implemented. Data processing environment 100 includes network 102. Network 102 is the medium used to provide communications links between various devices and computers connected together within data processing environment 100. Network 102 may include connections, such as wire, wireless communication links, or fiber optic cables.

Clients or servers are only example roles of certain data processing systems connected to network 102 and are not intended to exclude other configurations or roles for these data processing systems. Server 104 and server 106 couple to network 102 along with storage unit 108. Software applications may execute on any computer in data processing environment 100. Clients 110, 112, and 114 are also coupled to network 102. A data processing system, such as server 104 or 106, or client 110, 112, or 114 may contain data and may have software applications or software tools executing thereon.

Only as an example, and without implying any limitation to such architecture, FIG. 1 depicts certain components that are usable in an example implementation of an embodiment. For example, servers 104 and 106, and clients 110, 112, 114, are depicted as servers and clients only as example and not to imply a limitation to a client-server architecture. As another example, an embodiment can be distributed across several data processing systems and a data network as shown, whereas another embodiment can be implemented on a single data processing system within the scope of the illustrative embodiments. Data processing systems 104, 106, 110, 112, and 114 also represent example nodes in a cluster, partitions, and other configurations suitable for implementing an embodiment.

Device 132 is an example of a device described herein. For example, device 132 can take the form of a smartphone, a tablet computer, a laptop computer, client 110 in a stationary or a portable form, a wearable computing device, or any other suitable device. Any software application described as executing in another data processing system in FIG. 1 can be configured to execute in device 132 in a similar manner. Any data or information stored or produced in another data processing system in FIG. 1 can be configured to be stored or produced in device 132 in a similar manner.

Application 105 implements an embodiment described herein. Fabrication system 107 is any suitable system for fabricating a PCB. Application 105 provides instructions to system 107 for fabricating one or more PCBs in a manner described herein.

Servers 104 and 106, storage unit 108, and clients 110, 112, and 114 may couple to network 102 using wired connections, wireless communication protocols, or other suitable data connectivity. Clients 110, 112, and 114 may be, for example, personal computers or network computers.

In the depicted example, server 104 may provide data, such as boot files, operating system images, and applications to clients 110, 112, and 114. Clients 110, 112, and 114 may be clients to server 104 in this example. Clients 110, 112, 114, or some combination thereof, may include their own data, boot files, operating system images, and applications. Data processing environment 100 may include additional servers, clients, and other devices that are not shown.

In the depicted example, data processing environment 100 may be the Internet. Network 102 may represent a collection of networks and gateways that use the Transmission Control Protocol/Internet Protocol (TCP/IP) and other protocols to communicate with one another. At the heart of the Internet is a backbone of data communication links between major nodes or host computers, including thousands of commercial, governmental, educational, and other computer systems that route data and messages. Of course, data processing environment 100 also may be implemented as a number of different types of networks, such as for example, an intranet, a local area network (LAN), or a wide area network (WAN). FIG. 1 is intended as an example, and not as an architectural limitation for the different illustrative embodiments.

Among other uses, data processing environment 100 may be used for implementing a client-server environment in which the illustrative embodiments may be implemented. A client-server environment enables software applications and data to be distributed across a network such that an application functions by using the interactivity between a client data processing system and a server data processing system. Data processing environment 100 may also employ a service oriented architecture where interoperable software components distributed across a network may be packaged together as coherent business applications.

With reference to FIG. 2, this figure depicts a block diagram of a data processing system in which illustrative embodiments may be implemented. Data processing system 200 is an example of a computer, such as servers 104 and 106, or clients 110, 112, and 114 in FIG. 1, or another type of device in which computer usable program code or instructions implementing the processes may be located for the illustrative embodiments.

Data processing system 200 is also representative of a data processing system or a configuration therein, such as data processing system 132 in FIG. 1 in which computer usable program code or instructions implementing the processes of the illustrative embodiments may be located. Data processing system 200 is described as a computer only as an example, without being limited thereto. Implementations in the form of other devices, such as device 132 in FIG. 1, may modify data processing system 200, such as by adding a touch interface, and even eliminate certain depicted components from data processing system 200 without departing from the general description of the operations and functions of data processing system 200 described herein.

In the depicted example, data processing system 200 employs a hub architecture including North Bridge and memory controller hub (NB/MCH) 202 and South Bridge and input/output (I/O) controller hub (SB/ICH) 204. Processing unit 206, main memory 208, and graphics processor 210 are coupled to North Bridge and memory controller hub (NB/MCH) 202. Processing unit 206 may contain one or more processors and may be implemented using one or more heterogeneous processor systems. Processing unit 206 may be a multi-core processor. Graphics processor 210 may be coupled to NB/MCH 202 through an accelerated graphics port (AGP) in certain implementations.

In the depicted example, local area network (LAN) adapter 212 is coupled to South Bridge and I/O controller hub (SB/ICH) 204. Audio adapter 216, keyboard and mouse adapter 220, modem 222, read only memory (ROM) 224, universal serial bus (USB) and other ports 232, and PCI/PCIe devices 234 are coupled to South Bridge and I/O controller hub 204 through bus 238. Hard disk drive (HDD) or solid-state drive (SSD) 226 and CD-ROM 230 are coupled to South Bridge and I/O controller hub 204 through bus 240. PCI/PCIe devices 234 may include, for example, Ethernet adapters, add-in cards, and PC cards for notebook computers. PCI uses a card bus controller, while PCIe does not. ROM 224 may be, for example, a flash binary input/output system (BIOS). Hard disk drive 226 and CD-ROM 230 may use, for example, an integrated drive electronics (IDE), serial advanced technology attachment (SATA) interface, or variants such as external-SATA (eSATA) and micro-SATA (mSATA). A super I/O (SIO) device 236 may be coupled to South Bridge and I/O controller hub (SB/ICH) 204 through bus 238.

Memories, such as main memory 208, ROM 224, or flash memory (not shown), are some examples of computer usable storage devices. Hard disk drive or solid state drive 226, CD-ROM 230, and other similarly usable devices are some examples of computer usable storage devices including a computer usable storage medium.

An operating system runs on processing unit 206. The operating system coordinates and provides control of various components within data processing system 200 in FIG. 2. The operating system may be a commercially available operating system such as AIX® (AIX is a trademark of International Business Machines Corporation in the United States and other countries), Microsoft® Windows® (Microsoft and Windows are trademarks of Microsoft Corporation in the United States and other countries), Linux® (Linux is a trademark of Linus Torvalds in the United States and other countries), iOS™ (iOS is a trademark of Cisco Systems, Inc. licensed to Apple Inc. in the United States and in other countries), or Android™ (Android is a trademark of Google Inc., in the United States and in other countries). An object oriented programming system, such as the Java™ programming system, may run in conjunction with the operating system and provide calls to the operating system from Java™ programs or applications executing on data processing system 200 (Java and all Java-based trademarks and logos are trademarks or registered trademarks of Oracle Corporation and/or its affiliates).

Instructions for the operating system, the object-oriented programming system, and applications or programs, such as application 105 in FIG. 1, are located on storage devices, such as in the form of code 226A on hard disk drive 226, and may be loaded into at least one of one or more memories, such as main memory 208, for execution by processing unit 206. The processes of the illustrative embodiments may be performed by processing unit 206 using computer implemented instructions, which may be located in a memory, such as, for example, main memory 208, read only memory 224, or in one or more peripheral devices.

Furthermore, in one case, code 226A may be downloaded over network 201A from remote system 201B, where similar code 201C is stored on a storage device 201D. in another case, code 226A may be downloaded over network 201A to remote system 201B, where downloaded code 201C is stored on a storage device 201D.

The hardware in FIGS. 1-2 may vary depending on the implementation. Other internal hardware or peripheral devices, such as flash memory, equivalent non-volatile memory, or optical disk drives and the like, may be used in addition to or in place of the hardware depicted in FIGS. 1-2. In addition, the processes of the illustrative embodiments may be applied to a multiprocessor data processing system.

In some illustrative examples, data processing system 200 may be a personal digital assistant (PDA), which is generally configured with flash memory to provide non-volatile memory for storing operating system files and/or user-generated data. A bus system may comprise one or more buses, such as a system bus, an I/O bus, and a PCI bus. Of course, the bus system may be implemented using any type of communications fabric or architecture that provides for a transfer of data between different components or devices attached to the fabric or architecture.

A communications unit may include one or more devices used to transmit and receive data, such as a modem or a network adapter. A memory may be, for example, main memory 208 or a cache, such as the cache found in North Bridge and memory controller hub 202. A processing unit may include one or more processors or CPUs.

The depicted examples in FIGS. 1-2 and above-described examples are not meant to imply architectural limitations. For example, data processing system 200 also may be a tablet computer, laptop computer, or telephone device in addition to taking the form of a mobile or wearable device.

Where a computer or data processing system is described as a virtual machine, a virtual device, or a virtual component, the virtual machine, virtual device, or the virtual component operates in the manner of data processing system 200 using virtualized manifestation of some or all components depicted in data processing system 200. For example, in a virtual machine, virtual device, or virtual component, processing unit 206 is manifested as a virtualized instance of all or some number of hardware processing units 206 available in a host data processing system, main memory 208 is manifested as a virtualized instance of all or some portion of main memory 208 that may be available in the host data processing system, and disk 226 is manifested as a virtualized instance of all or some portion of disk 226 that may be available in the host data processing system. The host data processing system in such cases is represented by data processing system 200.

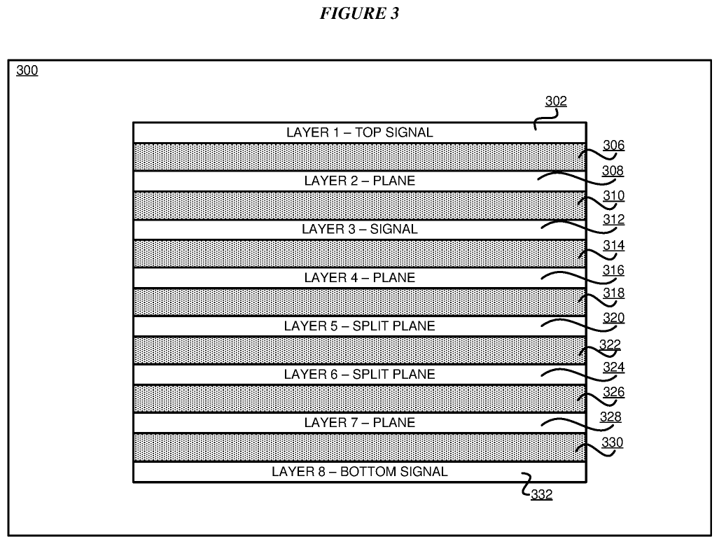

With reference to FIG. 3, this figure depicts a cross-section view of a portion of a process in which fabrication system 107 receives a PCB stack 300 according to an illustrative embodiment. PCB stack 300 includes a first conducting layer (layer 1) 302, a first insulating substrate layer 306, a second conducting layer (layer 2) 308, a second insulating substrate layer 310, a third conducting layer (layer 3) 312, a third insulating substrate layer 314, a fourth conducting layer (layer 4) 316, a fourth insulating substrate layer 318, a fifth conducting layer (layer 5) 320, a fifth insulating substrate layer 322, a sixth conducting layer (layer 6) 324, a sixth insulating substrate layer 326, a seventh conducting layer (layer 7) 328, a seventh insulating substrate layer 330, and an eighth conducting layer (layer 8) 332.

In the embodiment, first conducting layer 302, is disposed on first insulating substrate layer 306 and function as a top signal layer. Second conducting layer 308 is disposed between first insulating substrate layer 306 and second insulating substrate layer 310 and functions as a plane layer. Third conducting layer 312 is disposed between second insulating substrate layer 310 and third insulating substrate layer 314 and functions as a signal layer. Fourth conducting layer 316 is disposed between third insulating substrate layer 314 and fourth insulating substrate layer 318 and functions as a plane layer.

Fifth conducting layer 320 is disposed between fourth insulating substrate layer 318 and fifth insulating substrate layer 322 and functions as a split plane layer. Sixth conducting layer 324 is disposed between fifth insulating substrate layer 322 and sixth insulating substrate layer 326 and functions as a split plane layer. Seventh conducting layer 328 is disposed between sixth insulating substrate layer 326 and seventh insulating substrate layer 330 and functions as a plane layer. Eighth conducting layer 332 is disposed in contact with seventh insulating substrate layer 330 and functions as a bottom signal layer.

Although embodiments described herein are shown as using eight conducting layers and seven insulating substrate layers in a PCB stack, it should be understood that in other embodiments any desired number of conducting or insulating substrate layers forming the PCB stack may be used.

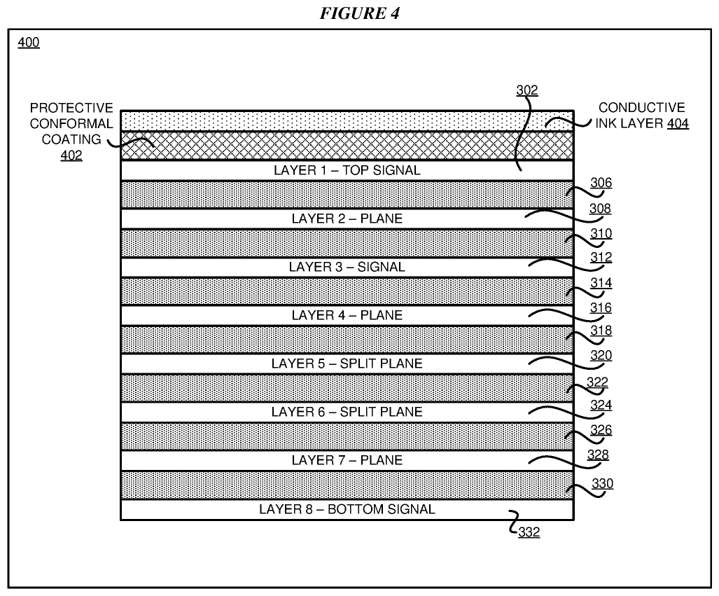

With reference to FIG. 4, this figure depicts a cross-section view of another portion of the process in which a structure 400 is formed according to an embodiment. In the embodiment, fabrication system 107 deposits a protective conformal coating layer 402 on an exterior surface of first conducting layer 302. In one or more embodiments, protective conformal coating layer 402 is an insulative layer. In the embodiment, the fabrication system 107 further applies a conductive ink layer 404 using a stenciling or silk-screening process to apply a conductive ink to form one or more conductive features upon protective conformal coating layer 402. In particular embodiments, the conductive features include one or more of signal connection features, signal referencing features, signal shielding features, and PCB reworking features. In a particular embodiment, a signal referencing feature is a conductive feature coupled to an existing signal line of the PCB to allow external referencing of the signal line. In another particular embodiment, a signal shielding feature is a conductive feature positioned proximate to an electronic component or signal line of the PCB to provide additional shielding to the electronic component or signal line.

Although the embodiment illustrated in FIG. 4 depicts protective conformal coating layer 402 and conductive ink layer 404 as being applied to first conducting layer 302, it should be understood that in other embodiments, protective conformal coating layer 402 and conductive ink layer 404 may instead be applied to eighth conducting layer 332, or to both first conducting layer 302 and eighth conducting layer 332.

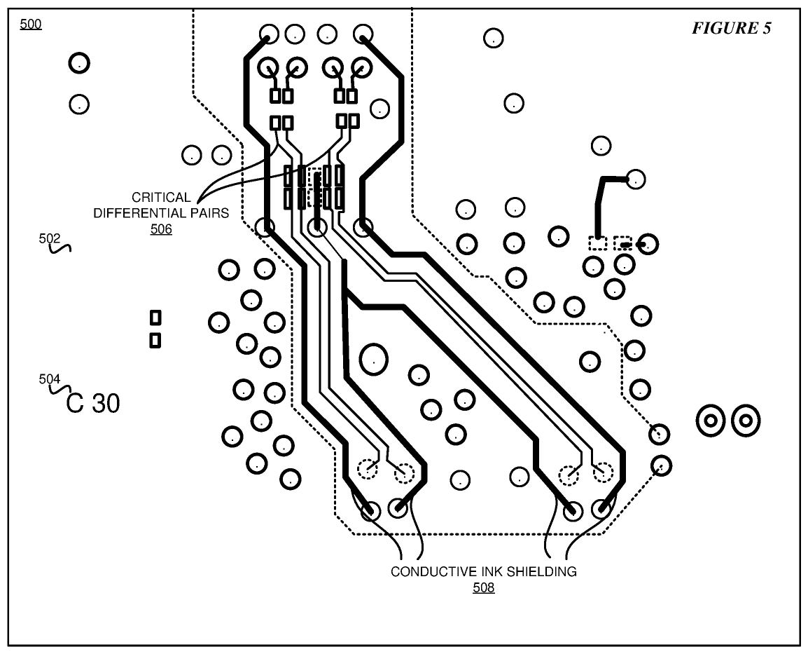

With reference to FIG. 5, this figure depicts a top view of a PCB stack 500 having conductive features formed using conductive ink by a stenciling or silk-screening process in accordance with an illustrative embodiment. In the embodiment, an external layer 502 of PCB stack 500 includes a component identifier 504 formed by a conventional silk-screening process. The external layer further includes critical differential pairs 506 formed on the external layer 502. Critical differential pairs 506 provide for differential signaling within PCB stack 500. PCB stack 500 further conductive ink shielding features 508 as conductive features formed by applying conductive ink in a pattern of conductive ink shielding features 508 using a stenciling or silk-screening process. In the embodiment, conductive ink shielding features 508 provide shielding for critical differential pairs 506.

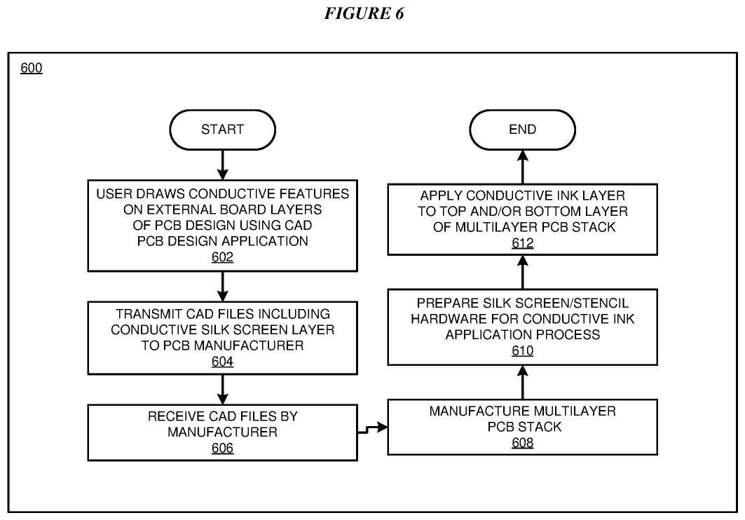

With reference to FIG. 6, this figure depicts a flowchart of an example process 600 for designing and fabricating printed circuit boards using conductive ink for forming signal connection, signal referencing, and shielding features in accordance with an illustrative embodiment. In block 602, a user, such as a PCB designer, uses a CAD PCB design application to draw conductive ink silk-screen features on one or more external board layers of a PCB design using a conductive silk-screen layer. In a particular embodiment, a user interfaces with the CAD PCB design application using a client device such as one or more of clients 110, 112, 114, and device 132 of FIG. 1. In block 604, the user transmits CAD files including the conductive ink silk-screen layer to a PCB manufacturer.

In block 606, the manufacturer receives the CAD files. In a particular embodiment, the manufacturer receives the CAD files at a server over a network. In block 608, the PCB manufacturer fabricates a multilayer PCB stack, or alternately receives an already fabricated multiplayer PCB stack. In block 610, the manufacturer prepares silk-screening/stenciling hardware for use with conductive ink. In block 612, the silk-screening/stenciling hardware applies the conductive ink to one or more portions of a top layer and/or bottom layer of the PCB stack using a silk-screening or stenciling process to form conductive features on the top and/or the bottom layers of the PCB stack. Process 600 then ends.

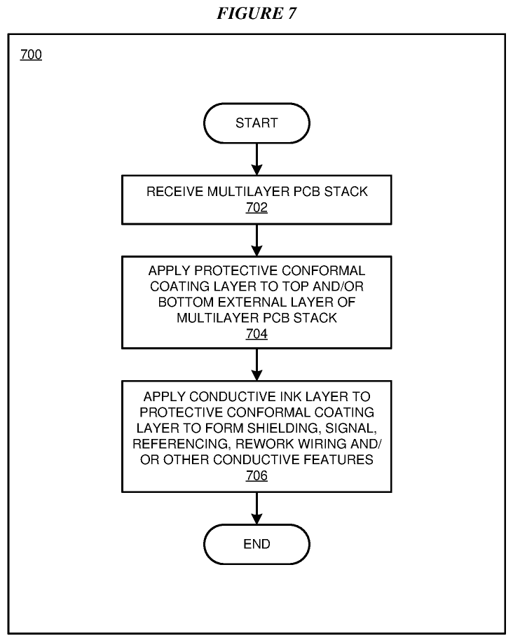

With reference to FIG. 7, this figure depicts a flowchart of an example process 700 for fabricating printed circuit boards using conductive ink for forming conductive features in accordance with an illustrative embodiment. In block 702, fabrication system 107 receives a multilayer PCB stack. In block 704, fabrication system 107 applies a protective conformal coating layer to a top and/or bottom external layer of the multilayer PCB stack. In a particular embodiment, fabrication system 107 applies the protective conformal coating using a suitable deposition process.

In block 706, fabrication system 107 applies conductive ink to one or more portions of the protective conformal coating layer using a silk-screening and/or stenciling process to form conductive features on the top and/or the bottom layers of the PCB stack. In particular embodiments, the conductive features include one or more of signal shielding, signal referencing, rework wiring, or other conductive features. Process 700 then ends.

Thus, a computer implemented method is provided in the illustrative embodiments for fabricating printed circuit boards using conductive ink for forming signal referencing and shielding and other related features, functions, or operations. Where an embodiment or a portion thereof is described with respect to a type of device, the computer implemented method, system or apparatus, the computer program product, or a portion thereof, are adapted or configured for use with a suitable and comparable manifestation of that type of device.

Where an embodiment is described as implemented in an application, the delivery of the application in a Software as a Service (SaaS) model is contemplated within the scope of the illustrative embodiments. In a SaaS model, the capability of the application implementing an embodiment is provided to a user by executing the application in a cloud infrastructure. The user can access the application using a variety of client devices through a thin client interface such as a web browser (e.g., web-based e-mail), or other light-weight client-applications. The user does not manage or control the underlying cloud infrastructure including the network, servers, operating systems, or the storage of the cloud infrastructure. In some cases, the user may not even manage or control the capabilities of the SaaS application. In some other cases, the SaaS implementation of the application may permit a possible exception of limited user-specific application configuration settings.

The present invention may be a system, a method, and/or a computer program product at any possible technical detail level of integration. The computer program product may include a computer readable storage medium (or media) having computer readable program instructions thereon for causing a processor to carry out aspects of the present invention.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, configuration data for integrated circuitry, or either source code or object code written in any combination of one or more programming languages, including an object oriented programming language such as Smalltalk, C++, or the like, and procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

1. A method comprising:
receiving a printed circuit board (PCB) stack having a plurality of layers;
applying a conformal coating layer to one or more external layers of the plurality of layers; and
applying conductive ink to one or more portions of the conformal coating layer to form one or more conductive features on the conformal coating layer.

2. The method of claim 1, wherein the conductive ink is applied using a silk-screening process.

3. The method of claim 1, wherein the conductive ink is applied using a stenciling process.

4. The method of claim 1, wherein the one or more conductive feature includes a signal referencing feature.

5. The method of claim 4, wherein the signal referencing feature is coupled to a signal line of the PCB to allow external referencing of the signal line.

6. The method of claim 1, wherein the one or more conductive features includes a signal shielding feature.

7. The method of claim 6, wherein the signal shielding feature is positioned proximate to one or more of an electronic component or a signal line of the PCB.

8. The method of claim 1, wherein the one or more conductive features includes rework wiring.

9. The method of claim 1, wherein the one or more conductive features includes a signal connection feature.

10. The method of claim 1, wherein the one or more external layers includes a conductive layer of the PCB stack.

11. An apparatus comprising:
a printed circuit board (PCB) stack having a plurality of layers;
a conformal coating layer applied to one or more external layers of the plurality of layers; and
a conductive ink applied on to a surface of the conformal coating layer, the conductive ink forming one or more conductive features on the surface of the conformal coating layer, wherein the one or more conductive features includes rework wiring.

12. The apparatus of claim 11, wherein the conductive ink is capable of being applied using a silk-screening process.

13. The apparatus of claim 11, wherein the conductive ink is capable of being applied using a stenciling process.

14. The apparatus of claim 11, wherein the one or more conductive feature includes a signal referencing feature.

15. The apparatus of claim 14, wherein the signal referencing feature is coupled to a signal line of the PCB to allow external referencing of the signal line.

16. (canceled)

17. The apparatus of claim 11, wherein the one or more conductive features includes a signal shielding feature positioned proximate to one or more of an electronic component or a signal line of the PCB.

18. A computer usable program product comprising one or more computer-readable storage devices, and program instructions stored on at least one of the one or more storage devices, the stored program instructions comprising:
program instructions to receive a printed circuit board (PCB) stack having a plurality of layers;
program instructions to apply a conformal coating layer to one or more external layers of the plurality of layers; and
program instructions to apply conductive ink to one or more portions of the conformal coating layer to form one or more conductive features on the conformal coating layer.

19. The computer usable program product of claim 18, wherein the computer usable code is stored in a computer readable storage device in a data processing system, and wherein the computer usable code is transferred over a network from a remote data processing system.

20. The computer usable program product of claim 15, wherein the computer usable code is stored in a computer readable storage device in a server data processing system, and wherein the computer usable code is downloaded over a network to a remote data processing system for use in a computer readable storage device associated with the remote data processing system.
